(19) United States
(12) Patent Application Publication
(10) Pub. No.: US 2009/0289327 A1
(43) Pub. Date: Nov. 26, 2009

(54) CAPACITOR INSULATING FILM AND METHOD FOR FORMING THE SAME, AND CAPACITOR AND SEMICONDUCTOR DEVICE

(75) Inventor: Naonori Fujiwara, Tokyo (JP)

Correspondence Address: MCDERMOTT WILL & EMERY LLP, 600 13TH STREET, N.W., WASHINGTON, DC, 20005-3096, US

(73) Assignee: ELPIDA MEMORY, INC.

(21) Appl. No.: 12/470,075

(22) Filed: May 21, 2009

(30) Foreign Application Priority Data
May 26, 2008 (JP) JP 2008-136848

(51) Int. Cl. H01L 29/92; B05D 5/12; H01G 4/10; H01G 4/008; B32B 7/02

(52) U.S. Cl. 257/532; 427/79; 361/322; 361/305; 428/213; 257/E29.342

(57) ABSTRACT

A capacitor insulating film includes a laminated structure in which aluminum oxide films and titanium dioxide films are alternately laminated, wherein the titanium dioxide films each have a rutile crystal structure, and the ratio of the total thickness of the aluminum oxide films to the total thickness of the laminated structure ranges from 3 to 8%.

### BACKGROUND OF THE INVENTION

1. Field of the Invention

The present invention relates to a capacitor insulating film and a method for forming the same, and a capacitor using the insulating film and a semiconductor device.

2. Description of Related Art

The progress in DRAM miniaturization and high packing density has led to decrease in size of a capacitor that forms a memory cell, and it has therefore been difficult to ensure an adequate amount of accumulated electric charge. To ensure the amount of accumulated electric charge, a capacitor using an insulating film having a high dielectric constant is under development (Japanese Patent Laid-Open No. 2007-129190 and Japanese Patent Laid-Open No. 2006-173175).

In a capacitor used in a DRAM memory cell, it is important to not only have an insulating film with a high dielectric constant but also suppress the leak current flowing through the insulating film.

Among a variety of high dielectric constant films, a titanium dioxide (TiO₂) film is considered as a promising candidate as a high dielectric constant film for a capacitor because it has a large relative dielectric constant ranging from 30 to 50 when it has an anatase crystal structure and a significantly large relative dielectric constant ranging from 80 to 100 when it has a rutile crystal structure, which is readily formed.

Titanium dioxide, with which a high dielectric constant insulating film can be readily formed, however, has a band gap as small as approximately 3 eV, which makes it very difficult to suppress the leak current. As a method for suppressing the leak current, it is conceivable that the electrodes are made of platinum (Pt) or ruthenium (Ru), which has a large work function. In this case, however, use of any of the noble metals as the electrode material disadvantageously results in increase in cost and difficulty in processing.

### SUMMARY

In one embodiment, there is provided a capacitor insulating film including:

a laminated structure in which aluminum oxide films and titanium dioxide films are alternately laminated,

wherein the titanium dioxide films each have a rutile crystal structure, and

a ratio of the total thickness of the aluminum oxide films to the total thickness of the laminated structure ranges from 3 to 8%.

In another embodiment, there is provided the capacitor insulating film described above wherein the ratio of the total thickness of the aluminum oxide films to the total thickness of the laminated structure ranges from 5 to 8%.

In another embodiment, there is provided any one of the capacitor insulating films described above, wherein the aluminum oxide films each have the thickness substantially equivalent to a single aluminum-atom layer.

In another embodiment, there is provided any one of the capacitor insulating films described above, wherein the titanium dioxide films are directly laminated on the aluminum oxide films.

In another embodiment, there is provided a capacitor including:

a first electrode;

a second electrode; and

any one of the capacitor insulating films described above sandwiched between the first and second electrodes.

In another embodiment, there is provided the capacitor described above, wherein the first and second electrodes are composed of titanium nitride.

In another embodiment, there is provided a semiconductor device including any one of the capacitors described above.

In another embodiment, there is provided a semiconductor device including a DRAM including any one of the capacitors described above.

In another embodiment, there is provided a method for forming a capacitor insulating film, including:

forming a film having a laminated structure in which aluminum oxide films and titanium dioxide films are alternately laminated; and

carrying out a heat treatment to form a rutile crystal structure in each of the titanium dioxide films,

wherein a ratio of the total thickness of the aluminum oxide films to the total thickness of the film having the laminated structure ranges from 3 to 8%.

In another embodiment, there is provided the method for forming a capacitor insulating film described above, wherein the heat treatment is carried out at a temperature ranging from 500 to 650° C.

In another embodiment, there is provided any of the methods for forming a capacitor insulating film described above, wherein the aluminum oxide films are formed such that the aluminum oxide films each have the thickness substantially equivalent to a single aluminum-atom layer.

In another embodiment, there is provided any one of the methods for forming a capacitor insulating film described above, wherein the titanium dioxide films are directly formed on the aluminum oxide films.

In another embodiment, there is provided any one of the methods for forming a capacitor insulating film described above, wherein the aluminum oxide films and the titanium dioxide films are formed by atomic layer deposition (ALD).

According to exemplary embodiments, it is possible to provide a capacitor insulating film capable of not only increasing the dielectric constant but also suppressing the leak current and a method for forming the same, and a capacitor using the insulating film and a semiconductor device.

### BRIEF DESCRIPTION OF THE DRAWINGS

The above features and advantages of the present invention will be more apparent from the following description of certain preferred embodiments taken in conjunction with the accompanying drawings, in which:

FIG. 1 is a cross-sectional view of a capacitor element according to an embodiment of the present invention;

FIG. 2 is a process flow diagram in accordance with which an insulating film is formed;

FIGS. 3A and 3B are cross-sectional views of capacitor elements according to other embodiments of the present invention;

FIG. 4 is a plan view of DRAM memory cells to each of which a capacitor element according to an embodiment of the present invention is applied;

FIG. 5 is a cross-sectional view of the DRAM memory cells to each of which a capacitor element according to an embodiment of the present invention is applied;

FIG. 6 shows the equivalent oxide thickness (EOT) of an insulating film in a capacitor element versus the content of aluminum oxide in the insulating film; and

FIG. 7 shows the leak current flowing through an insulating film in a capacitor element versus the content of aluminum oxide in the insulating film.

### DETAILED DESCRIPTION OF THE PREFERRED EMBODIMENTS

Preferred embodiments of the present invention will be described below.

### First Embodiment

A capacitor insulating film of an embodiment of the present invention will be described with reference to the drawings.

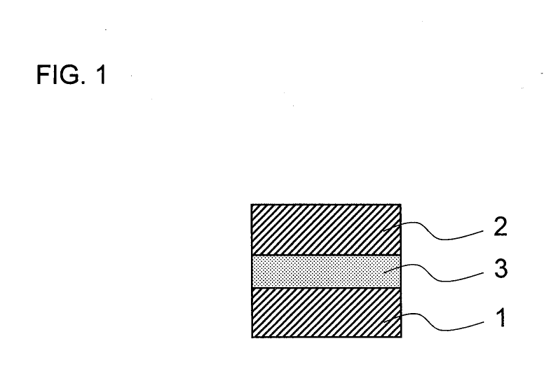

FIG. 1 is a cross-sectional view of a capacitor element formed by using a capacitor insulating film of the present embodiment. The capacitor element has a structure in which electrodes 1 and 2 made of titanium nitride (TiN) sandwich an insulating film 3. Titanium nitride is typically used as an electrode material and readily processed. In the present invention, the material of the electrodes 1 and 2 is not particularly limited to titanium nitride, but can be, for example, other refractory metals. Examples of other electrode materials include Pt, Ru, RuO₂, Ir, IrO₂, Au, TaN, Ni, and MoN.

The insulating film 3 is composed of a film having a laminated structure in which a titanium dioxide (TiO₂) film and an aluminum oxide (Al₂O₃) film are alternately laminated (hereinafter described as a “TiAlO film”). The insulating film can be controlled in such a way that the content of the aluminum oxide range, for example, from 5 to 8%. The content of the aluminum oxide is preferably 3% or higher, more preferably 5% or higher, to suppress the leak current, which will be described later, but preferably 8% or lower, more preferably 7% or lower, in consideration of the equivalent oxide thickness.

The content of aluminum oxide used herein is expressed in the ratio (percentage) of the total thickness of the portion made of aluminum oxide to the total thickness of the insulating film. The laminated structure used herein means that a two-layer structure composed of a titanium dioxide film and an aluminum oxide film is repeated at least twice.

The bottom layer of the laminated structure is preferably an aluminum oxide film because heat treatment at 600° C. or lower can change the structure of a titanium dioxide film formed on the aluminum oxide film to a rutile crystal structure.

The thickness (total thickness) of the capacitor insulating film of the present embodiment preferably ranges from 6 to 12 nm to adequately provide the desired advantageous effects.

A method for manufacturing such an insulating film and capacitor element will be described below.

A TiAlO film can be formed by atomic layer deposition (ALD), which excels in coating characteristic. An example of a titanium material gas for forming a titanium dioxide film is tetrakis(ethylmethylamino)titanium (TEMAT). An example of an aluminum material gas for forming an aluminum oxide film is trimethyl aluminum (TMA). An example of an oxidizing material gas necessary for an oxidation reaction is ozone (O₃).

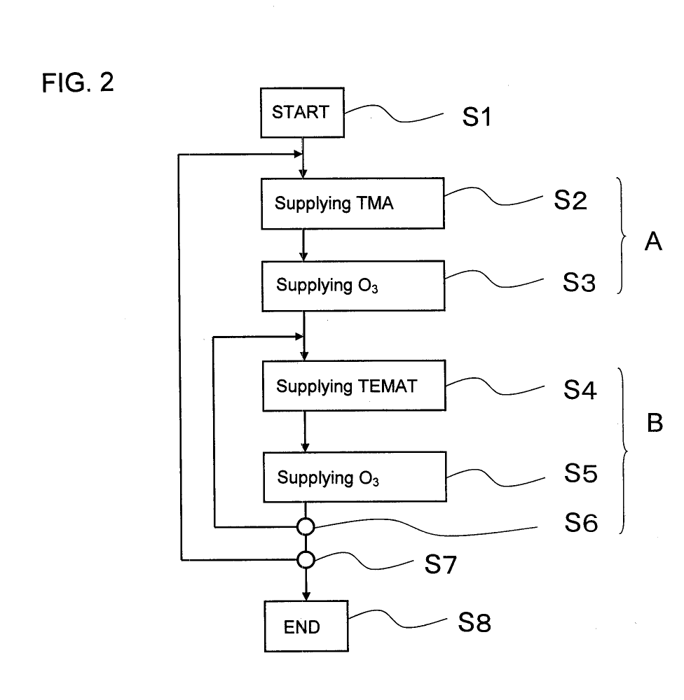

FIG. 2 shows a process flow in accordance with which an insulating film is formed by atomic layer deposition.

In the step S1 (start step), a semiconductor substrate in which one of the electrodes (lower electrode) of a capacitor is formed by using titanium nitride is placed in a reaction chamber of a film deposition apparatus.

In the step S2 (TMA supplying step), the temperature of the semiconductor substrate is maintained at a predetermined value (230° C., for example), and TMA gas is introduced into the reaction chamber with the pressure therein maintained at a predetermined value (60 Pa, for example). The aluminum material (TMA) is then adsorbed on the surface of the electrode to form a film. The period during which the TMA gas is introduced may be adjusted as appropriate in consideration of the shape of the electrode so that a uniform film is formed on the surface of the electrode. The TMA gas that has not been adsorbed is discharged from the reaction chamber by carrying out inert gas purging and vacuuming.

In the step S3 (O₃ supplying step), the temperature of the semiconductor substrate is maintained at a predetermined value, and O₃ gas is introduced into the reaction chamber with the pressure therein maintained at a predetermined value. The O₃ gas then chemically reacts with the TMA film that has been formed, and an aluminum oxide film is formed as an oxide resulting from the reaction. The period during which the O₃ gas is introduced may be adjusted as appropriate so that a uniform aluminum oxide film is formed on the surface of the electrode. The O₃ gas that has not reacted is discharged from the reaction chamber by carrying out inert gas purging and vacuuming. The aluminum oxide film formed in the step S3 is a thin film having a thickness on the order of the atomic size (equivalent to the thickness of a single aluminum-atom layer (monolayer)).

In the step S4 (TEMAT supplying step), the temperature of the semiconductor substrate is maintained at a predetermined value (230° C., for example), and TEMAT gas is introduced into the reaction chamber with the pressure therein maintained at a predetermined value (60 Pa, for example). The titanium material (TEMAT) is then adsorbed on the surface of the film formed on the base substrate to form a film. The period during which the TEMAT gas is introduced may be adjusted as appropriate in consideration of the shape of the electrode so that a uniform film is formed on the surface of the electrode. The TEMAT gas that has not been adsorbed is discharged from the reaction chamber by carrying out inert gas purging and vacuuming.

In the step S5 (O₃ supplying step), the temperature of the semiconductor substrate is maintained at a predetermined value and O₃ gas is introduced into the reaction chamber with the pressure therein maintained at a predetermined value. The O₃ gas then chemically reacts with the TEMAT film that has been formed, and a titanium dioxide film is formed as an oxide resulting from the reaction. The period during which the O₃ gas is introduced may be adjusted as appropriate so that a uniform titanium dioxide film is formed on the surface of the electrode. The O₃ gas that has not reacted is discharged from the reaction chamber by carrying out inert gas purging and vacuuming. The titanium dioxide film formed in the step S5 is a thin film having a thickness on the order of the atomic size (equivalent to the thickness of a single titanium-atom layer (monolayer)).

The steps S4 and S5 are repeated several times until the thickness of the titanium dioxide film becomes a preset desired value. That is, the number of repetitions of the steps S4 and S5 is set in advance, and it is judged in the step S6 (judging step) whether or not the thus set number is reached. The series of steps is repeated until the specified number is reached. The steps S4 to S6 that are repeated are described as a step B.

To achieve a preset content of the aluminum oxide film in the target insulating film, a step A composed of the steps S2 and S3 and the step B are repeated several times. That is, the number of repetitions of the series of steps composed of the steps A and B is set in advance, and it is judged in the step S7 (judging step) whether or not the thus set number is reached. The series of steps is repeated until the specified number is reached. In this procedure, every time the aluminum oxide film having a thickness on the order of the atomic size is formed in the step A, the titanium dioxide film having a predetermined thickness is formed in the step B. Repeating the steps A and B at least twice provides an insulating film in which the aluminum oxide and the titanium dioxide are laminated. The content of the aluminum oxide can be set by adjusting the thickness of the titanium dioxide film formed in the step B and the number of repetitions of the steps A and B.

The total content of the aluminum oxide film in the target insulating film (TiAlO film) is adjusted in such a way that the ratio of the thickness of the aluminum oxide film to the total thickness of the insulating film ranges, for example, from 5 to 8%.

After a predetermined insulating film is formed, the semiconductor substrate is removed from the reaction chamber in the step S8 (end step).

The temperature, pressure, and other film forming conditions described above are presented by way of example, and can be changed.

A heat treatment performed on the thus formed insulating film will be described below.

The TiAlO film immediately after it is formed in the processes described with reference to FIG. 2 is an amorphous film.

A titanium dioxide film, when the structure thereof is changed to a rutile crystal structure, becomes an insulating film having a large dielectric constant. The amorphous TiAlO film in which the titanium dioxide film and the aluminum oxide film are formed and laminated can also have a large dielectric constant when the structure of the titanium dioxide is changed to a rutile crystal structure. When the content of the aluminum oxide in the TiAlO film is too high, however, the heat treatment needs to be carried out at a high temperature, that is, at least 700° C., in order to achieve a rutile crystal structure, and such a high temperature could adversely affect a DRAM or any other semiconductor device on which the capacitor element is mounted (for example, increase in contact resistance of contact plugs and degradation in transistor characteristics). When the content of the aluminum oxide is appropriate, a rutile crystal structure can be formed at a relatively low temperature, whereas when the content of the aluminum oxide is too low, the leak current increases and the breakdown voltage decreases. Setting the total content of the aluminum oxide in the TiAlO film within a specific range allows an insulating film having an adequate breakdown voltage and a large dielectric constant to be formed at a relatively low temperature.

The temperature of the heat treatment for converting the amorphous titanium dioxide film formed in the processes described above into a titanium dioxide film having a rutile crystal structure is preferably 500° C. or higher, more preferably 550° C. or higher, but preferably 650° C. or lower, more preferably 600° C. or lower. When the heat treatment temperature is too low, an adequate rutile crystal structure is difficult to form, whereas when the heat treatment temperature is too high, the semiconductor device could be adversely affected as described above.

Specifically, the heat treatment may be carried out, for example, for approximately 10 minutes in a nitrogen atmosphere or an inert gas (such as argon) atmosphere containing oxygen at 600° C.

Thereafter, the other electrode (upper electrode) of the capacitor is formed by using titanium nitride. The capacitor element is thus completed. It is noted that the two electrodes that sandwich the insulating film are not necessarily made of the same material, but may be made of different materials.

### Second Embodiment

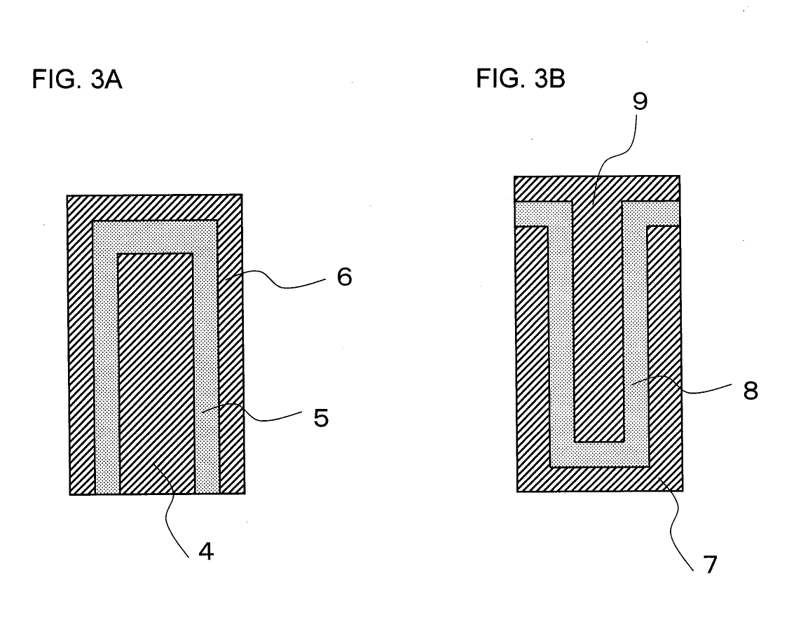

A capacitor insulating film according to another embodiment of the present invention can be applied to not only the flat-shaped electrodes shown in FIG. 1 (first embodiment), but also three-dimensionally structured electrodes shown in FIGS. 3A and 3B.

Three-dimensionally structured capacitor elements will be described with reference to FIGS. 3A and 3B.

FIG. 3A is a longitudinal cross-sectional view of a solid-cylinder-shaped (pillar-shaped) capacitor element to which a capacitor insulating film of the present embodiment is applied. Reference numeral 4 denotes a solid-cylinder-shaped lower electrode made of titanium nitride or any other suitable refractory metal. Reference numeral 5 denotes a capacitor insulating film (TiAlO film) formed in accordance with the method described above in such a way that the insulating film covers the upper and side portions of the lower electrode 4. Reference numeral 6 denotes an upper electrode made of titanium nitride or any other suitable refractory metal and formed so as to cover the insulating film 5.

FIG. 3B is a longitudinal cross-sectional view of a hollow-cylinder-shaped (cylinder-shaped) capacitor element to which a capacitor insulating film of the present embodiment is applied. Reference numeral 7 denotes a hollow-cylinder-shaped lower electrode made of titanium nitride or any other suitable refractory metal. Reference numeral 8 denotes a capacitor insulating film formed in accordance with the method described above in such a way that the insulating film covers the inner wall and the upper portion of the lower electrode 7. Reference numeral 9 denotes an upper electrode made of titanium nitride or any other suitable refractory metal and formed so as to cover the insulating film 8.

In each of the three-dimensionally structured electrodes as well, adjusting, for example, the period during which a source gas (the steps S2 and S4 in FIG. 2) and an oxidation reaction gas (the steps S3 and S5 in FIG. 2) used to form the insulating film are supplied allows a TiAlO film having a uniform thickness to be formed on the surface of the electrode.

Employing the three-dimensionally structured electrodes shown in FIGS. 3A and 3B allows formation of a capacitor element with the capacitance increased but the footprint unchanged.

### Third Embodiment

An embodiment of a DRAM having memory cells to each of which the capacitor element according to the embodiment of the present invention is applied will be described below.

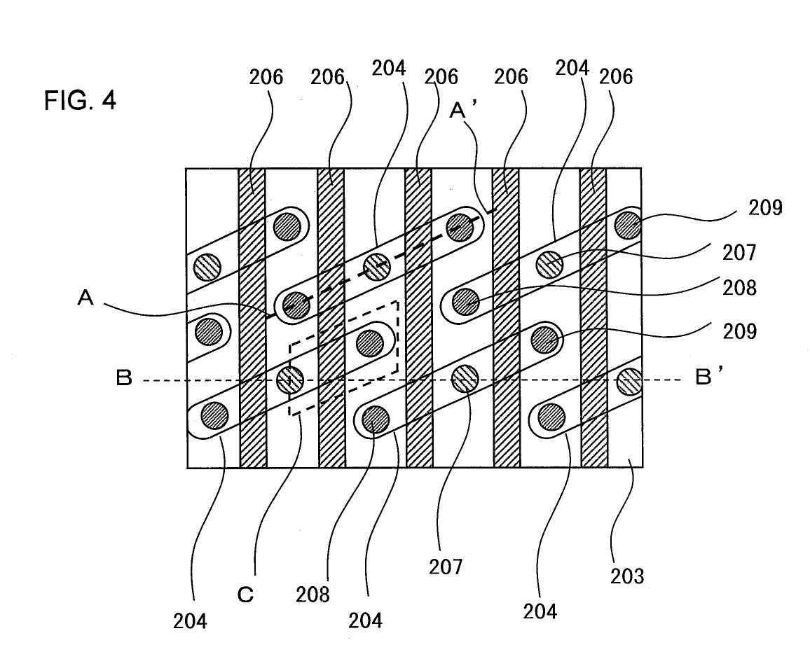

FIG. 4 is a plan view of the DRAM memory cells and shows only part of the memory cells for the sake of description.

In FIG. 4, a plurality of active regions (diffusion layer regions) 204 are regularly arranged on a semiconductor substrate (not shown). The active regions 204 are partitioned by an element isolation region 203. The element isolation region 203 is formed in accordance with a typical method by burying a silicon oxide film or any other suitable insulating film in a trench formed in the semiconductor substrate. A plurality of gate electrodes 206 are disposed in such a way that they intersect the active regions 204. The gate electrodes 206 function as word lines of the DRAM. Phosphorus or any other suitable impurity is ion-implanted into the regions of the active regions 204 that are not covered with the gate electrodes 206 to form N-type diffusion layer regions. The N-type diffusion layers function as source and drain regions of transistors. The portion surrounded by the broken line C in FIG. 4 forms a single MOS transistor.

A contact plug 207 is provided at a central portion of each of the active regions 204 and in contact with the corresponding N-type diffusion layer region in the surface of the active region 204. Contact plugs 208 and 209 are provided at both ends of each of the active regions 204 and in contact with the corresponding N-type diffusion layer regions in the surface of the active region 204. The contact plugs 207, 208, and 209 can be formed simultaneously.

In the layout described above, two adjacent transistors are disposed to share a single contact plug 207 in order to arrange the memory cells at a high density.

In a later step, a plurality of wiring layers (not shown) that are in contact with the contact plug 207 and perpendicular to the gate electrodes 206 are formed in the direction indicated by the line B-B′. The wiring layers function as bit lines of the DRAM. Capacitor elements (not shown) are connected to the contact plugs 208 and 209.

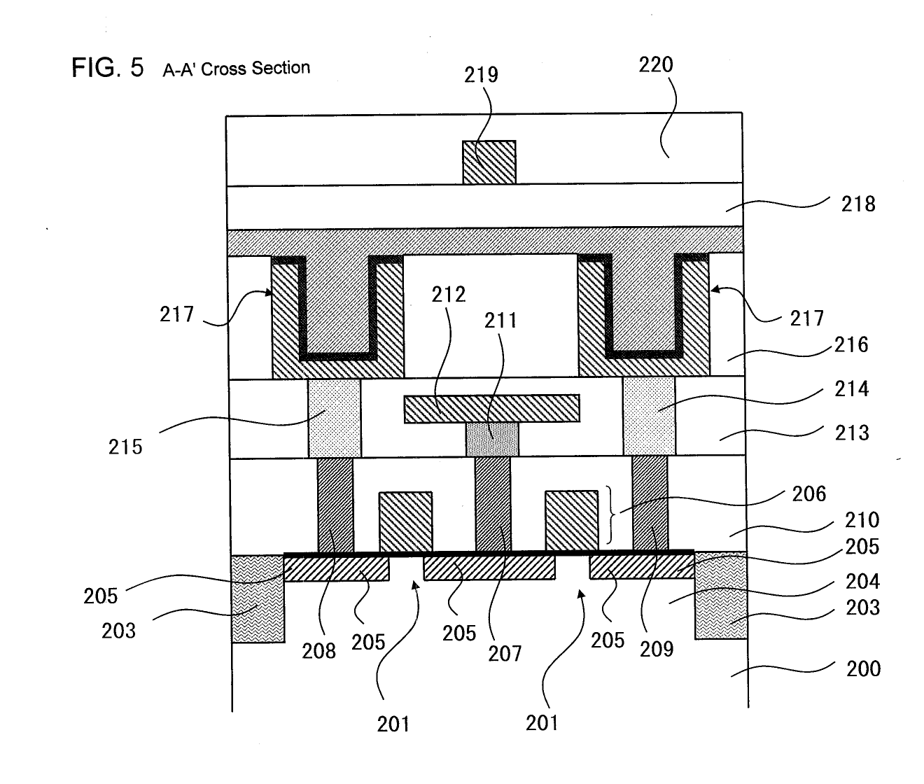

FIG. 5 is a cross-sectional view of a completed DRAM memory cell taken along the line A-A′ in FIG. 4. In FIG. 5, reference numeral 200 denotes a semiconductor substrate made of P-type silicon. Reference numeral 201 denotes a MOS transistor. Reference numeral 206 denotes the gate electrodes, which function as word lines. The N-type diffusion layer regions 205 are formed in the surface of the active region 204 and in contact with the contact plugs 207, 208, and 209. The contact plugs 207, 208, and 209 can be made of polycrystalline silicon to which phosphorous is introduced. Reference numeral 210 denotes an interlayer insulating film provided on the transistors. The contact plug 207 is connected to a wiring layer 212 that functions as a bit line through a via plug 211 separately provided. The wiring layer 212 can be made of tungsten. The contact plugs 208 and 209 are connected to capacitor elements 217 through via plugs 214 and 215 separately provided. In the embodiment, while each of the capacitor elements has a hollow-cylinder shape described with reference to FIG. 3(B), the capacitor element can have other shapes.

Reference numerals 213, 216, and 218 denote interlayer insulating films for insulating a wiring layer from the other. Reference numeral 219 denotes a wiring layer located on the upper layer side and made of aluminum or any other suitable material. Reference numeral 220 denotes a surface protective film.

When any of the MOS transistors 201 is turned on, it can be judged whether or not electric charge is accumulated in the corresponding capacitor element 217 by using the corresponding bit line (wiring layer 212), and the corresponding DRAM memory cell is operated to store information.

The capacitor element according to the present invention, in which not only does the insulating film have a large dielectric constant but also the leak current can be suppressed, can form a memory cell having an excellent electric charge holding characteristic (refresh characteristic). A high-performance DRAM can thus be readily manufactured.

The capacitor element according to the embodiment of the present invention is also applicable to other products as well as a DRAM memory cell. For example, the capacitor element according to the embodiment of the present invention is applicable to any other typical semiconductor device as long as it uses a capacitor element, such as a logic product with no memory cell.

### Advantages of Example of Insulating Film According to Embodiments of the Present Invention Over Comparative Examples

To specifically explain the advantages of the capacitor insulating film according to embodiments of the present invention, the electric characteristics thereof versus the content of the aluminum oxide in the TiAlO film will be described.

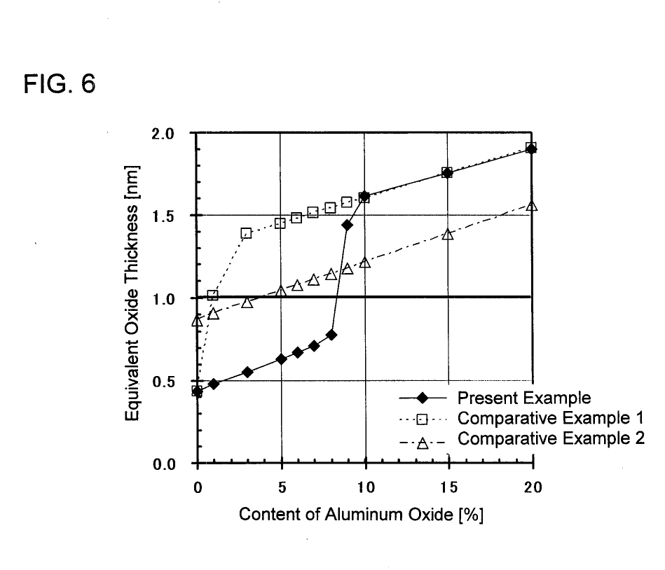

For a capacitor using an insulating film formed in accordance with the method described above (present example) and capacitors using two types of insulating films formed in accordance with the methods described below (comparative examples 1 and 2), FIG. 6 shows measurement results of the equivalent oxide thickness (EOT) of the insulating films. The horizontal axis represents the content of the aluminum oxide in the insulating film expressed in the ratio of the film thickness of the aluminum oxide to the total thickness of the insulating film. The upper and lower electrodes were made of titanium nitride.

The insulating film of the present example was produced by forming a TiAlO film (the thickness of which is 10 nm) having a laminate structure in accordance with the method described in the first embodiment, followed by a heat treatment in a nitrogen atmosphere at 600° C. for 10 minutes.

The insulating film of the comparative example 1 is a laminated film having a two-layer structure in which a titanium dioxide film is laminated on an aluminum oxide film, and the insulating film of the comparative example 2 is a laminated film having a two-layer structure in which an aluminum oxide film is laminated on a titanium dioxide film. In the comparative examples 1 and 2, as in the case of the insulating film of the present example, the film thickness ratio of the aluminum oxide film to the total film thickness is changed to change the content of aluminum in the oxide film. In the comparative examples 1 and 2, the total film thickness was 10 nm, and the heat treatment performed after the insulating film formation was carried out in a nitrogen atmosphere at 600° C. for 10 minutes, as in the case of the insulating film of the present example.

In a case where each of the capacitor elements is used as a DRAM memory cell, a highly integrated device manufactured in accordance with a 70-μm design rule or a smaller design rule requires a high dielectric constant insulating film the equivalent oxide thickness (EOT) of which is typically 1 nm or smaller.

As seen from the measurement results shown in FIG. 6, the capacitor element formed by using the insulating film of the present example has an equivalent oxide thickness of 1 nm or smaller when the content of the aluminum oxide is 8% or lower, hence the dielectric constant of the capacitor element can meet the requirement. The reason why a high dielectric constant is obtained is that the insulating film of the present example (the TiAlO film having a laminated structure), which is an amorphous film immediately after the formation, undergoes a heat treatment at 600° C. whereby the structure of the film is changed to a rutile crystal structure without going through an anatase crystal structure.

On the other hand, the aluminum oxide film in the two-layer structured film of the comparative example 1 is thicker than the aluminum oxide film having a thickness on the order of the atomic size formed in the insulating film of the present example. Since the titanium dioxide film formed on the thick aluminum oxide film is not crystallized at 600° C., the dielectric constant is small and the required equivalent oxide thickness of 1 nm or smaller cannot be achieved.

Further, the two-layer structured film of the comparative example 1 in which the titanium dioxide film is formed on the thick aluminum oxide film has a crystalline state in which the anatase crystal and the rutile crystal are mixed even after undergoing a heat treatment at 700° C. It is therefore difficult to obtain a high dielectric constant.

In the two-layer structured film of the comparative example 2, since a titanium dioxide film is first formed on the lower electrode, the titanium dioxide film immediately after the formation has an anatase crystal structure.

The dielectric constant is not increased by a heat treatment at 600° C. because it is necessary to carry out the heat treatment at 700° C. or higher to fully change the anatase crystal structure to a rutile crystal structure. In the comparative example 2, although the equivalent oxide thickness is 1 nm or smaller when the content of the aluminum oxide is lower than or equal to 3%, it is difficult to use the resultant film as a capacitor insulating film due to the problem of leak current, which will be described later.

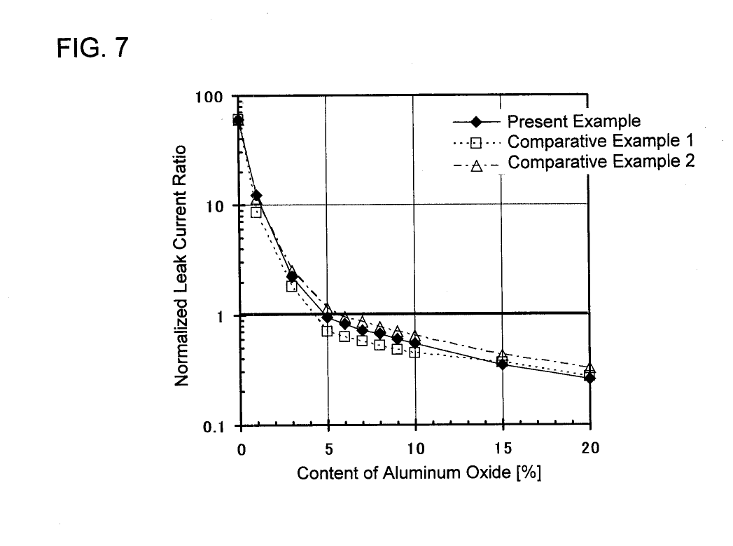

FIG. 7 shows leak current evaluation results for the capacitor elements formed by using the three types of insulating films of the present example, the comparative example 1, and the comparative example 2. The vertical axis in FIG. 7 represents the magnitude of leak current normalized by a target magnitude of acceptable leak current when the capacitor elements are used in DRAM memory cells. When the vertical coordinate is 1 or smaller, any of the insulating films is suitable for a capacitor element for a DRAM. The horizontal axis represents the content (film thickness ratio) of the aluminum oxide in the insulating film, as in the case of FIG. 6. The electrodes were made of titanium nitride.

Referring to FIG. 7, the leak current flowing through any of the insulating films of the present example, the comparative example 1, and the comparative example 2 is very large when the proportion of the aluminum oxide film is lower than 3%. It is therefore difficult to use any of the insulating films in a capacitor element for a DRAM. The reason why the leak current is large is that a low proportion of the aluminum oxide film does not allow the aluminum oxide film to adequately suppress the leak current.

Referring to the evaluation results shown in FIG. 7 in combination with the equivalent oxide thickness evaluation results shown in FIG. 6, it is found difficult to set an aluminum oxide content that satisfies both the equivalent oxide thickness and the leak current in the comparative examples 1 and 2. It is therefore difficult to use the two-layer structured TiAlO films of the comparative examples 1 and 2 in a capacitor element for a DRAM. The reason why the comparative example 1 achieves the lowest magnitude of the leak current is that the titanium dioxide film formed on the thick aluminum oxide film is not crystallized in a heat treatment at 600° C. but stays amorphous.

On the other hand, in the insulating film of the present example (the TiAlO film having a laminated structure), the magnitude of the leak current is low and the dielectric constant is high when the proportion of the aluminum oxide film ranges from 3 to 8%, preferably 5 to 8%, whereby the insulating film of the present example can be suitably used in a capacitor element for a DRAM.

That is, the capacitor insulating film according to the embodiment of the present invention has a laminated structure in which a titanium dioxide film and an aluminum oxide film are laminated, and hence provides a large dielectric constant and a low leak current even when the electrodes are made of a typical material, such as titanium nitride, as long as the content of aluminum oxide falls within a specific range. Further, since a desired insulating film can be formed without a heat treatment at a high temperature higher than 700° C. in the manufacturing processes, a semiconductor device can be manufactured without any adverse effect on the transistor characteristics, contact resistance of contact plugs, and other properties.

It is therefore possible to readily manufacture a high-performance DRAM by using a capacitor element using the insulating film according to the embodiment of the present invention. Further, the use of the capacitor element according to the embodiment of the present invention is not limited to a DRAM, but allows other high-performance semiconductor devices to be readily manufactured.

It is apparent that the present invention is not limited to the above embodiments, but may be modified and changed without departing from the scope and spirit of the invention.

What is claimed is:

1. A capacitor insulating film comprising:
a laminated structure in which aluminum oxide films and titanium dioxide films are alternately laminated,
wherein the titanium dioxide films each have a rutile crystal structure, and
a ratio of the total thickness of the aluminum oxide films to the total thickness of the laminated structure ranges from 3 to 8%.

2. The capacitor insulating film according to claim 1, wherein the ratio of the total thickness of the aluminum oxide films to the total thickness of the laminated structure ranges from 5 to 8%.

3. The capacitor insulating film according to claim 1, wherein the aluminum oxide films each have the thickness substantially equivalent to a single aluminum-atom layer.

4. The capacitor insulating film according to claim 1, wherein the titanium dioxide films are directly laminated on the aluminum oxide films.

5. A capacitor comprising:
a first electrode;
a second electrode; and
an insulating film sandwiched between the first and second electrodes,
wherein the insulating film includes a laminated structure in which aluminum oxide films and titanium dioxide films are alternately laminated;
the titanium dioxide films each have a rutile crystal structure; and
a ratio of the total thickness of the aluminum oxide films to the total thickness of the laminated structure ranges from 3 to 8%.

6. The capacitor according to claim 5, wherein the first and second electrodes are composed of titanium nitride.

7. A semiconductor device comprising the capacitor as recited in claim 5.

8. A semiconductor device comprising a DRAM including the capacitor as recited in claim 5.

9. A method for forming a capacitor insulating film, comprising:
forming a film having a laminated structure in which aluminum oxide films and titanium dioxide films are alternately laminated; and
carrying out a heat treatment to form a rutile crystal structure in each of the titanium dioxide films,
wherein a ratio of the total thickness of the aluminum oxide films to the total thickness of the film having the laminated structure ranges from 3 to 8%.

10. The method for forming a capacitor insulating film according to claim 9, wherein the heat treatment is carried out at a temperature ranging from 500 to 650° C.

11. The method for forming a capacitor insulating film according to claim 9, wherein the aluminum oxide films are formed such that the aluminum oxide films each have the thickness substantially equivalent to a single aluminum-atom layer.

12. The method for forming a capacitor insulating film according to claim 9, wherein the titanium dioxide films are directly formed on the aluminum oxide films.

13. The method for forming a capacitor insulating film according to claim 9, wherein the aluminum oxide films and the titanium dioxide films are formed by atomic layer deposition (ALD).
